(19) United States
(12) Patent Application Publication
(10) Pub. No.: US 2016/0079195 A1
(43) Pub. Date: Mar. 17, 2016

(54) SEMICONDUCTOR DEVICE

(71) Applicant: KABUSHIKI KAISHA TOSHIBA, Tokyo (JP)

(72) Inventor: Jun TANAKA, Kuwana Mie (JP)

(21) Appl. No.: 14/636,085

(22) Filed: Mar. 2, 2015

(30) Foreign Application Priority Data
Sep. 17, 2014 (JP) 2014-188527

(51) Int. Cl. H01L 23/00; H01L 25/065; H01L 23/31

(52) U.S. Cl. CPC H01L 24/17; H01L 23/3142; H01L 24/09; H01L 25/0657; H01L 2224/1403; H01L 2224/1412; H01L 2224/0401; H01L 2224/1414; H01L 2224/1413; H01L 2224/1415; H01L 2224/13111; H01L 2224/13647; H01L 2224/13644; H01L 2224/13655; H01L 2924/2064; H01L 2224/05023; H01L 2224/05026; H01L 2224/16147; H01L 2224/16148; H01L 2224/16227; H01L 2225/06513; H01L 2225/06517

(57) ABSTRACT

A semiconductor device includes a first substrate and a second substrate facing the first substrate, each substrate having conductive pads disposed thereon, an insulating adhesive layer sealing the space between the first substrate and the second substrate, and a plurality of bumps penetrating the insulating adhesive layer and electrically connecting the plurality of first conductive pads and the plurality of second conductive pads. The plurality of bumps include at least a first bump having a first height and a second bump that is provided in a position closer to a geometric center of the second substrate than the first bump and has a second height greater than the first height.

### CROSS-REFERENCE TO RELATED APPLICATION

This application is based upon and claims the benefit of priority from Japanese Patent Application No. 2014-188527, filed Sep. 17, 2014, the entire contents of which are incorporated herein by reference.

### FIELD

Embodiments described herein relate generally to semiconductor devices.

### BACKGROUND

In flip-chip bonding, solder bumps are used to bond a semiconductor chip to a wiring board or another semiconductor chip. In one method, an insulating adhesive material such as a non-conductive film (NCF) is applied to seal the space concurrently with bonding of the semiconductor chip by the solder bumps. The insulating adhesive material such as the NCF has the function of both sealing and bonding and therefore eliminates the need for a process of filling an underfill.

In flip-chip bonding using the insulating adhesive material, since bonding by the bumps and sealing the space are performed at the same time, the flow of the insulating adhesive material may negatively affect bonding by the bumps. In order to suppress poor bonding, for example, the amount of the insulating adhesive material may be reduced. However, a reduction in the amount of the insulating adhesive material may cause voids to appear more easily. The appearance of voids tends to result in a lower degree of reliability such as an insufficient sealing state.

Therefore, there is a need for a method to improve bonding without diminishing device reliability.

### DESCRIPTION OF THE DRAWINGS

FIG. 1 is a diagram showing a semiconductor device according to one embodiment.

FIGS. 2A and 2B are cross-sectional views depicting a method for producing a semiconductor device according to one embodiment.

FIGS. 3A to 3C are a plan view (3A) and cross-sectional views (3B, 3C) depicting a semiconductor device according to one embodiment.

FIGS. 4A to 4C are a plan view (4A) and cross-sectional views (4B, 4C) depicting a semiconductor device according to another embodiment.

FIGS. 5A to 5C are a plan view (5A) and cross-sectional views (5B, 5C) depicting a semiconductor device according to another embodiment.

FIGS. 6A to 6C are a plan view (6A) and cross-sectional views (6B, 6C) depicting a semiconductor device according to another embodiment.

FIGS. 7A to 7C are a plan view (7A) and cross-sectional views (7B, 7C) depicting a semiconductor device according to another embodiment.

FIGS. 8A and 8B are a plan view (8A) and a cross-sectional view (8B) showing a semiconductor device according to another embodiment.

FIG. 9 is an enlarged cross-sectional view showing a detail of a semiconductor device according to an embodiment.

### DETAILED DESCRIPTION

In general, according to one embodiment, a semiconductor device includes: a first substrate having a surface; a plurality of first conductive pads provided on the surface of the first substrate; a second substrate having a surface; a plurality of second conductive pads provided below the surface of the second substrate, wherein the surface of the first substrate faces the surface of the second substrate; a sealing layer sealing a space between the first substrate and the second substrate; and a plurality of bumps electrically connecting the plurality of first conductive pads and the plurality of second conductive pads. The plurality of bumps include at least a first bump and a second bump, and the second bump is provided in a position closer to a geometric center of the second substrate than the first bump, the first bump having a first height, and the second bump having a second height greater than the first height.

Hereinafter, embodiments will be described with reference to the drawings. It is to be noted that the drawings are schematic drawings and, for example, the relationship between the thickness and the planar size and the thickness ratio between the layers are sometimes different from the actual relationship and thickness ratio. Moreover, in the embodiments, the substantially identical component elements are identified with the same characters and the descriptions thereof are omitted.

### First Embodiment

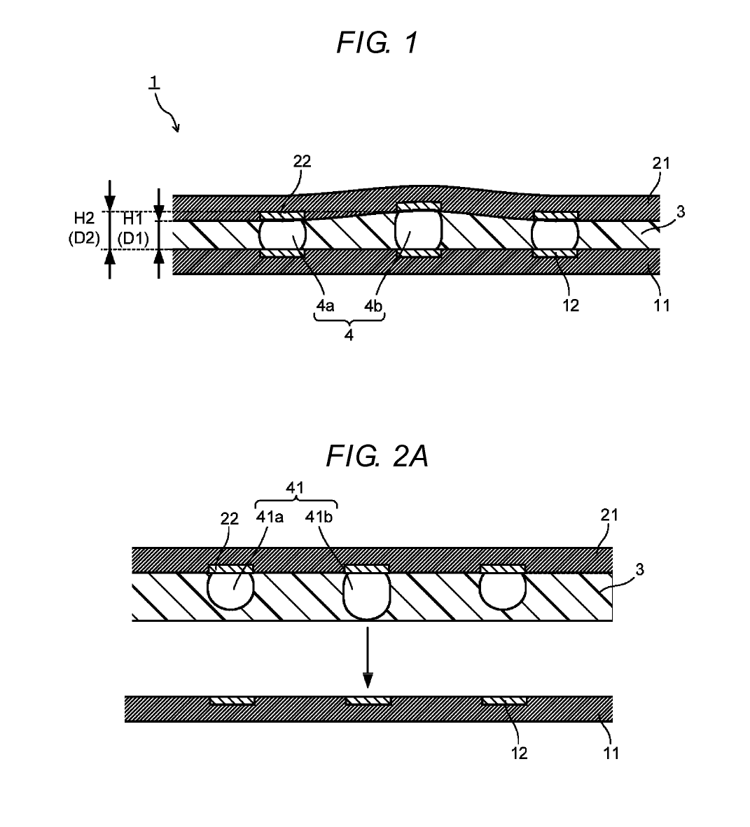

FIG. 1 is a diagram showing one embodiment of a semiconductor device. A semiconductor device 1 includes a first substrate 11 with a plurality of conductive pads 12 provided in at least a surface of the first substrate 11, and a second substrate 21 with a plurality of conductive pads 22 provided in at least a surface of the second substrate 21. The first substrate 11 and the second substrate 21 face each other such that the plurality of conductive pads 12 in the surface of the first substrate 11 may align with the plurality of conductive pads 22 in the second substrate 21. An insulating adhesive layer 3 is disposed between substrate 11 and substrate 21 to seal the space between the substrate 11 and the substrate 21. A plurality of bumps 4 is also disposed between the substrate 11 and the substrate 21 such that the bumps 4 connect the plurality of conductive pads 12 to the plurality of conductive pads 22. Incidentally, the numbers of the conductive pads 12, the numbers of the conductive pads 22, and the numbers of the bumps 4 are not limited to those depicted in FIG. 1.

The substrate 11 may include a semiconductor substrate such as a silicon substrate, a glass substrate, a resin substrate, a metal substrate, or the like. Moreover, the substrate 11 may have flexibility. Furthermore, a semiconductor device may be provided in the substrate 11. The substrate 11 forms at least a part of a semiconductor chip or a circuit board, for example. The substrate 11 has a rectangular planar shape such as a square shape.

The substrate 21 may include at least a semiconductor substrate such as a silicon substrate. A semiconductor device may be provided in the substrate 21. The substrate 21 forms at least a part of a semiconductor chip. The substrate 21 has a rectangular planar shape such as a square shape. A plurality of substrates 21 may be stacked on the substrate 11. In this case, the insulating adhesive layers 3 and the bumps 4 are also provided between the plurality of substrates 21. Moreover, at least one or both of the substrate 11 and the substrate 21 may have through electrodes, such as through silicon vias (TSVs), which penetrate the substrate. Some through electrodes may comprise conductive pads 12 or 22.

The conductive pads 12 and the conductive pads 22 may comprise metal materials such as aluminum, copper, and/or nickel. Incidentally, each conductive pad 12 may be regarded as a part of the substrate 11 and each conductive pad 22 may be regarded as a part of the substrate 21. Moreover, an insulating layer (not pictured) having openings (not pictured) on the conductive pads 12 or the conductive pads 22 may be provided on the substrate 11 and/or the substrate 21. The insulating layer may comprise, for example, a silicon oxide layer, a silicon nitride layer, or the like. In addition to the silicon oxide layer, the silicon nitride layer, or the like, an organic resin layer may be provided as another insulating layer. In addition, in the openings, metal bump layers (not pictured) may be provided on the conductive pads 12 and/or the conductive pads 22.

The insulating adhesive layer 3 serves as a sealing material that seals the space between the substrate 11 and the substrate 21. The insulating adhesive layer 3 may comprise, for example, a thermosetting insulating adhesive material such as an NCF, which has both an adhesive function and a sealing function. The insulating adhesive material 3 may include epoxy type resin, for example. The thickness of the insulating adhesive layer 3 may be between 5 μm and 60 μm, for example. This thickness serves to seal the space between the substrate 11 and the substrate 21 while suppressing the appearance of voids.

The insulating adhesive layer 3 is formed by, for example, bonding the substrate 11 and the substrate 21 together, melting the insulating adhesive layer material, flowing the melted insulating adhesive layer material in the space between the substrate 11 and the substrate 21, and then cooling the material to form the insulating adhesive layer. The flowability of the melted insulating adhesive material varies depending on whether the material is near the edges of the substrates or the geometric center. For example, the melted insulating adhesive material flows more easily near the outer edges of the substrates 11 and 21 because the melt flows to the outside of the space between the substrate 11 and the substrate 21 more easily. On the other hand, the melted insulating adhesive material flows less easily near the geometric center of the substrate 11 and the substrate 21 because the melted insulating adhesive material is likely to remain in the space between the substrate 11 and the substrate 21. This variable flow distribution results in a plurality of regions having different thicknesses in the insulating adhesive layer 3.

For example, as depicted in FIG. 1, the insulating adhesive layer 3 has a thickness gradient in which the insulating adhesive layer 3 is thicker near the geometric center of the substrates 11 and 21 than near the outer edges of the substrates 11 and 21. As a result, at least one of the substrates 11 and 21 sometimes curves depending on the thickness of the insulating adhesive layer 3. FIG. 1 depicts an example of a case in which the substrate 21 curves.

The plurality of bumps 4 penetrate the insulating adhesive layer 3 and electrically connect the plurality of conductive pads 12 on the first substrate 11 and the plurality of conductive pads 22 on the second substrate 21. The bumps 4 each include a solder bump layer and a metal bump layer. The solder bump layer comprises at least tin. For example, the solder bump layer may comprise tin-silver type or tin-silver-copper type lead-free solder. Alternatively, the solder bump layer may comprise a solder ball. The solder bump layer is disposed over the conductive pads 22 on the substrate 21. Opposite each of the solder bump layers is a metal bump layer disposed over a conductive pad 12 on substrate 11. The metal bump layer serves to suppress the diffusion of tin or the like contained in the solder bump layer. The metal bump layer comprises at least one of copper, nickel, and gold. For example, the metal bump layer may have a stacked structure including a copper layer and a nickel layer; a nickel layer and a gold layer; or a copper layer, a nickel layer, and a gold layer, or the like. The metal bump layer and the solder bump layer may be bonded to each other. Thus, the substrate 21 comprises conductive pads 22, over which are disposed solder bump layers, which bond to metal bump layers disposed over conductive pads 12 in substrate 11.

The heights of the plurality of bumps 4 are determined in accordance with the thickness of the anticipated insulating adhesive layer 3. For example, the plurality of bumps 4 includes at least a first bump 4a having a first height (thickness) and a second bump 4b that is closer to the geometric center of the substrates 11 and 21 than the first bump and has a second height (thickness) which is greater than the first height.

As described earlier, the insulating adhesive layer 3 has a plurality of regions with different thicknesses depending on the distance from the geometric center of the substrates 11 and 21. If each of the plurality of bumps 4 has the same height, the height of the bump 4 in a central region, in which the insulating adhesive layer 3 is thick, becomes insufficient to adequately connect conductive pad 12 on substrate 11 with conductive pad 22 on substrate 21. Thus, for example, as depicted in FIG. 1, a bump 4a is provided in a region of the insulating adhesive layer 3, where the bump 4A has a height (thickness) H1, the region has a thickness D1, and the bump height H1 is identical to the regional thickness D1. By contrast, a bump 4b is provided in a region of the insulating adhesive layer 3 that is closer to the geometric center having a thickness D1, where the bump 4B has a height (thickness) H2, the region has a thickness D2 which is greater than the thickness D1, and the bump height H2 is identical to the regional thickness D2. This makes it possible to suppress poor bonding by the bumps 4 despite varying thickness of the insulating adhesive layer. Based on the flow distribution in the insulating adhesive layer 3, it is preferable that a difference between the maximum value and the minimum value of the heights of the plurality of bumps 4 is between about 5 μm and about 20 μm, for example.

As described above, the insulating adhesive layer 3 has a thickness gradient in which the insulating adhesive layer 3 becomes gradually thicker toward the geometric center of the substrates 11 and 21 and thinner toward the outer edges of the substrates 11 and 21. The thickness gradient results in poor bonding at the geometric center of the substrates 11 and 21. To account for the thickness gradient, the bumps 4 are provided with different heights depending on the positions of the bumps 4. For example, bumps 4 that are nearer the geometric center of the substrates 11 and 21 have a height greater than bumps 4 that are nearer the outer edges of the substrates 11 and 21. The differential bump heights suppress poor bonding by compensating for the thickness differential in the insulating adhesive layer 3.

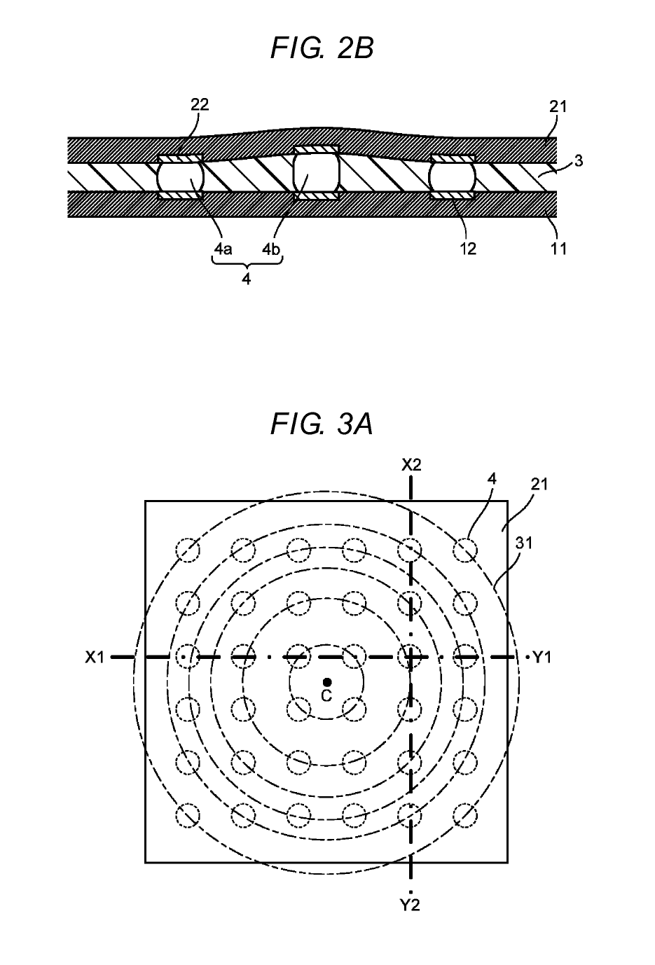

Next, an example of a method for manufacturing the semiconductor device will be described with reference to FIGS. 2A and 2B. FIGS. 2A and 2B are cross-sectional views depicting a method for manufacturing the semiconductor device.

First, as depicted in FIG. 2A, a substrate 11 with a plurality of conductive pads 12 and a substrate 21 with a plurality of conductive pads 22 are provided. On the plurality of conductive pads 22, a plurality of bump layers 41 is provided. The plurality of bumps 41 includes at least a bump layer 41a and a bump layer 41b, where bump layer 41b is closer to the geometric center of the substrate 21 than bump layer 41a. On the plurality of conductive pads 12 are disposed one or more of the metal bump layers described above.

For example, the bump layers 41 may be formed by applying a material to the conductive pads 22 by using electrolytic plating or electroless plating. By varying the plating time depending on the formation positions of the bumps 41 (for example, by changing the number of plating processes), it is possible to vary the heights of the bumps 41. The heights of the plurality of bumps 4 may also be varied by varying the heights of the metal bump layers disposed on the conductive pads 12 of the substrate 11 by using a method similar to that used for the bump layers 41.

Furthermore, an insulating adhesive layer 3 is formed in such a way that the plurality of bump layers 41 is embedded therein. For example, by pressure bonding a film-shaped insulating adhesive material to the substrate 21 with the plurality of bump layers 41 interposed between the film-shaped insulating adhesive material and the substrate 21, it is possible to form the insulating adhesive layer 3 in which the plurality of bump layers 41 is buried.

Next, as depicted in FIG. 2B, the substrate 11 and the substrate 21 are bonded together with the insulating adhesive layer 3 interposed between the substrate 11 and the substrate 21 in such a way that each of the bump layers 41 is placed on a corresponding one of the conductive pads 12. At least part of each of the bump layers 41 and the insulating adhesive layer 3 is melted by heat treatment and then cooled. Cooling results in hardening the insulating adhesive layer 3 and, at the same time, forming the bumps 4 disposed within the insulating adhesive layer 3 and electrically connecting the conductive pads 12 to the conductive pads 22. As the heat treatment, for example, it is preferable to perform temporary bonding at a temperature of less than 200° C. and then perform final bonding at a temperature of 200° C. or more. The heat treatment temperature is appropriately set in accordance with the material characteristics of the insulating adhesive layer 3. In this way, the semiconductor device is manufactured.

As described earlier, closer to the geometric center of the substrates 11 and 21, the melted insulating adhesive layer 3 is more likely to pool at the geometric center. By contrast, closer to the outer edges of the substrates 11 and 21, the melted insulating adhesive layer 3 is more likely to flow out beyond the edges of the substrates 11 and 21. As a result, at least one of the substrate 11 and the substrate 21 curves to accommodate the melted insulating adhesive layer pooling toward the geometric center of the substrates 11 and 21. Therefore, a plurality of regions of the insulating adhesive layer 3 is formed, with the regions having different thicknesses.

The flow distribution (the thickness gradient of the insulating adhesive layer 3) of the melted insulating adhesive layer 3 may be broadly classified into at least five types of flow distributions. The flow distribution of the melted insulating adhesive layer 3 varies in accordance with, for example, the planar shape, the flatness, and the like of the substrate 11 and/or the substrate 21 which makes contact with the insulating adhesive layer 3. Therefore, it is possible to predict the type of flow distribution of the melted insulating adhesive layer 3 based on the shape of the substrate 11 or the substrate 21 and thereby determine the placement and heights of the bumps 4 to be formed.

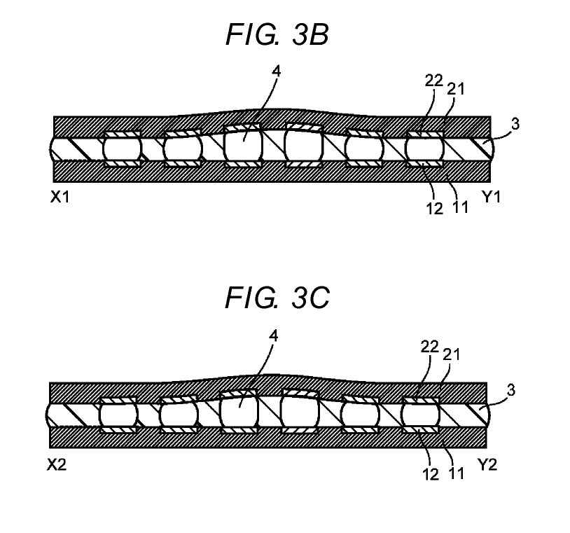

The types of flow distributions of the melted insulating adhesive layer 3 in the semiconductor device and examples of the placement of the plurality of bumps 4 having heights adjusted in accordance with the flow distribution will be described with reference to FIGS. 3A to 3C to FIGS. 7A to 7C. FIGS. 3A to 3C to FIGS. 7A to 7C are diagrams depicting the structural examples of the semiconductor device. FIGS. 3A, 4A, 5A, 6A, and 7A are plan views of the semiconductor device, FIGS. 3B, 4B, 5B, 6B, and 7B are cross-sectional views taken on the line X1-Y1 in FIGS. 3A, 4A, 5A, 6A, and 7A, respectively, and FIGS. 3C, 4C, 5C, 6C, and 7C are cross-sectional views taken on the line X2-Y2 in FIGS. 3A, 4A, 5A, 6A, and 7A, respectively. In FIGS. 3A, 4A, 5A, 6A, and 7A, for the sake of convenience, some component elements are omitted.

As is the case with the semiconductor device 1 depicted in FIG. 1, semiconductor devices depicted in FIGS. 3A to 3C to FIGS. 7A to 7C each include a first substrate 11 with a plurality of conductive pads 12 provided in at least a surface of the first substrate 11, and a second substrate 21 with a plurality of conductive pads 22 provided in at least a surface of the second substrate 21. The first substrate 11 and the second substrate 21 face each other such that the plurality of conductive pads 12 in the surface of the first substrate 11 may align with the plurality of conductive pads 22 in the second substrate 21. An insulating adhesive layer 3 is disposed between substrate 11 and substrate 21 to seal the space between the substrate 11 and the substrate 21. A plurality of bumps 4 is also disposed between the substrate 11 and the substrate 21 such that the bumps 4 connect the plurality of conductive pads 12 to the plurality of conductive pads 22. Because the descriptions of FIG. 1 and components depicted and described therein may be appropriately used to explain these component elements, descriptions thereof will be omitted here. In FIGS. 3A to 3C to FIGS. 7A to 7C, the planar shape of the substrate 11 and the substrate 21 is assumed to be a square shape. However, since the flow distribution of the insulating adhesive layer 3 varies also in accordance with the planar shape of the substrate 11 and the substrate 21, the substrate 11 and the substrate 21 may have other planar or relatively planar shapes. FIGS. 3A to 3C to FIGS. 7A to 7C depict an example providing 36 bumps 4 (=6 vertical bumps 4×6 horizontal bumps 4), but the number of bumps 4 is not limited to this example.

In the semiconductor device depicted in FIGS. 3A to 3C, the insulating adhesive layer 3 has a flow distribution that varies with the diameter of the concentric circles 31, which share the geometric center C of the substrate 21. The larger the diameter of the circle 31, the smaller the thickness of insulating adhesive layer 3 in a region located on the circumference of the circle 31.

If the insulating adhesive layer 3 has the above-described flow distribution, as depicted in FIGS. 3A to 3C, it is preferable to provide the plurality of bumps 4 such that, the larger the diameter of the circle 31, the less the height of the bump 4 located on the circumference of the circle 31. Moreover, if the insulating adhesive layer 3 has the above-described flow distribution, it is preferable that the bumps 4 located on the circumference of the same circle 31 have the same height.

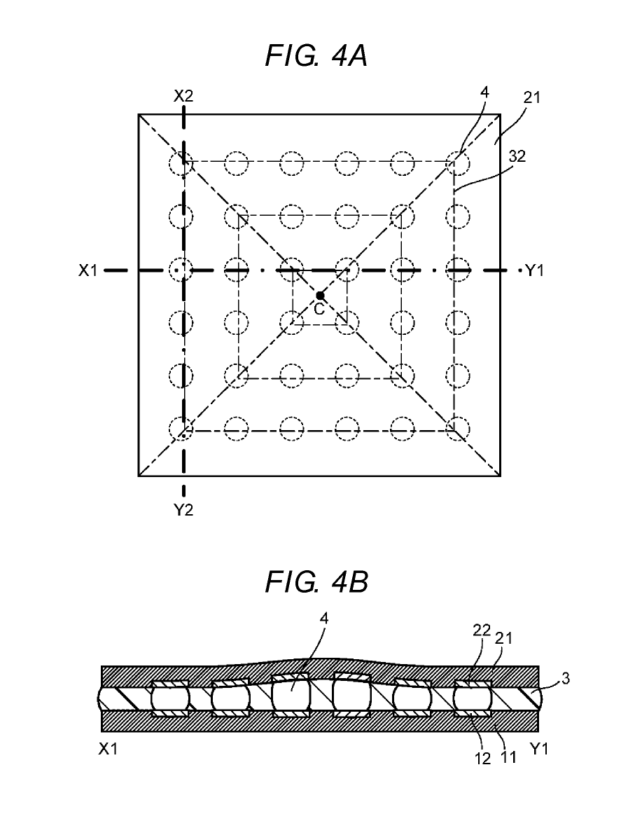

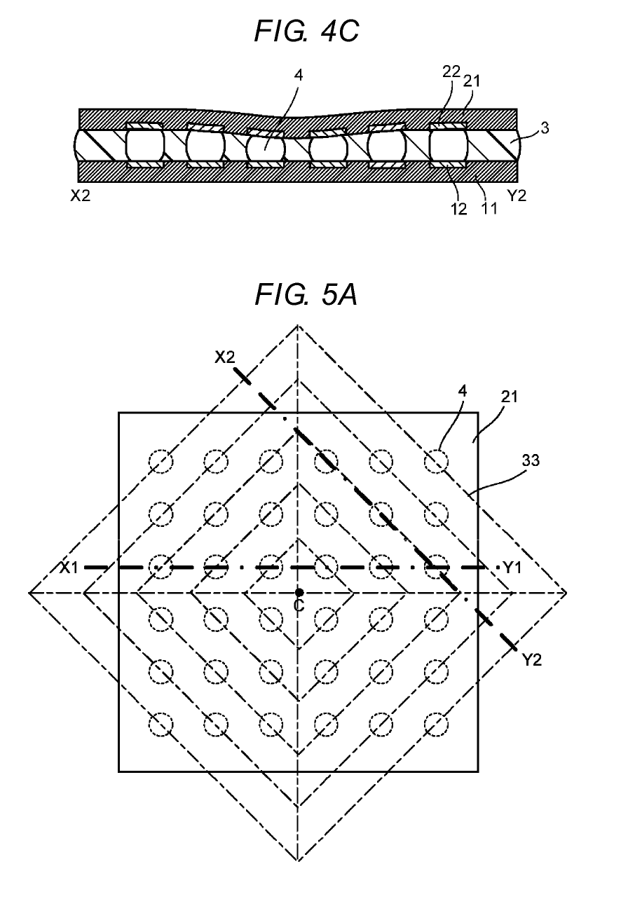

In the semiconductor device depicted in FIGS. 4A to 4C, the insulating adhesive layer 3 has a flow distribution that varies with the length of the diagonal of concentric squares 32, which share the geometric center C of the substrate 21 and have sides parallel to at least one side of the substrate 21. The larger the diagonal of the square 32, the smaller the thickness of insulating adhesive layer 3 in a region located on the perimeter of the square 32.

If the insulating adhesive layer 3 has the above-described flow distribution, as depicted in FIGS. 4A and 4B, it is preferable to provide the plurality of bumps 4 such that the longer the diagonal of the square 32, the less the height of the bump 4 located on the perimeter of the square 32. The bumps 4 located on the perimeter of the same square 32 may have the same height. However, if the insulating adhesive layer 3 has the above-described flow distribution, the insulating adhesive layer 3 is less likely to flow in the directions of the diagonal lines than in the directions of perpendiculars of the four sides passing through the geometric center of the square 32. Thus, as depicted in FIG. 4C, on the perimeter of the square 32, bumps 4 closer to the diagonal line of the square 32 may have a greater height than bumps 4 further from the diagonal line of the square.

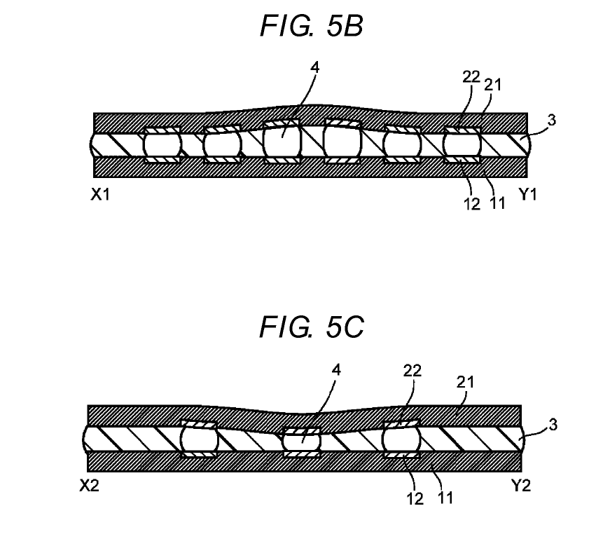

In the semiconductor device described in FIGS. 5A to 5C, the insulating adhesive layer 3 has a flow distribution that varies with the diagonals of concentric squares 33, which share the geometric center C of the substrate 21 and have diagonal lines perpendicular to at least one side of the substrate 21. The larger the square 33, the smaller the thickness of the insulating adhesive layer 3 in a region located on the perimeter of the square 33.

If the insulating adhesive layer 3 has the above-described flow distribution, as described in FIGS. 5A and 5B, it is preferable to provide the plurality of bumps 4 such that the longer the diagonal line of the square 33, the less the height of the bump 4 located on the perimeter of the square 33. The bumps 4 located on the perimeter of the same square 33 may have the same height. However, if the insulating adhesive layer 3 has the above-described flow distribution, the insulating adhesive layer 3 is less likely to flow in the directions of diagonal lines than in the directions of perpendiculars of the four sides passing through the geometric center of the square 33. Thus, as depicted in FIG. 5C, on the perimeter of the square 33, bumps 4 closer to the diagonal line of the square 33 may have a height greater than bumps 4 further from the diagonal line of the square.

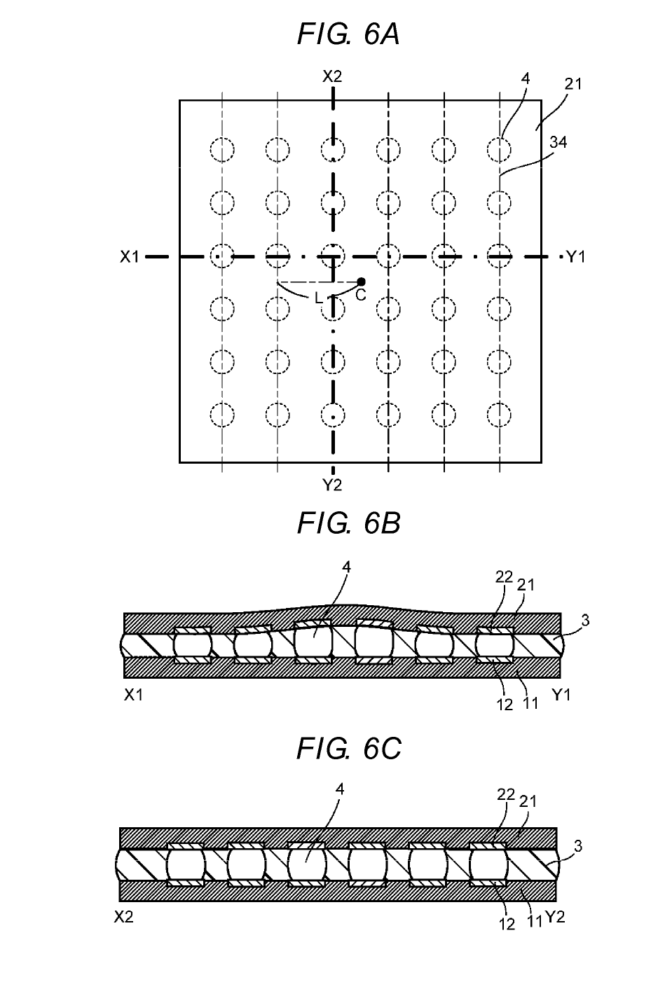

In the semiconductor device described in FIGS. 6A to 6C, when straight lines 34 perpendicularly intersecting one side of the substrate 21 are drawn along the plane of the substrate 21, the insulating adhesive layer 3 has a flow distribution that varies with the distance of the perpendicular from the geometric center of the substrate 21. The greater the distance L of a perpendicular between the straight line 34 and the geometric center C of the substrate 21, the smaller the thickness of a region located on the straight line 34.

If the insulating adhesive layer 3 has the above-described flow distribution, as described in FIGS. 6A and 6B, it is preferable to provide the plurality of bumps 4 such that bumps 4 on a straight line having a lesser distance L from the geometric center C may have a height greater than bumps 4 on a straight line having a greater distance L from the geometric center C. If the insulating adhesive layer 3 has the above-described flow distribution, as depicted in FIG. 6C, it is preferable that the bumps 4 located on the same straight line 34 have the same height.

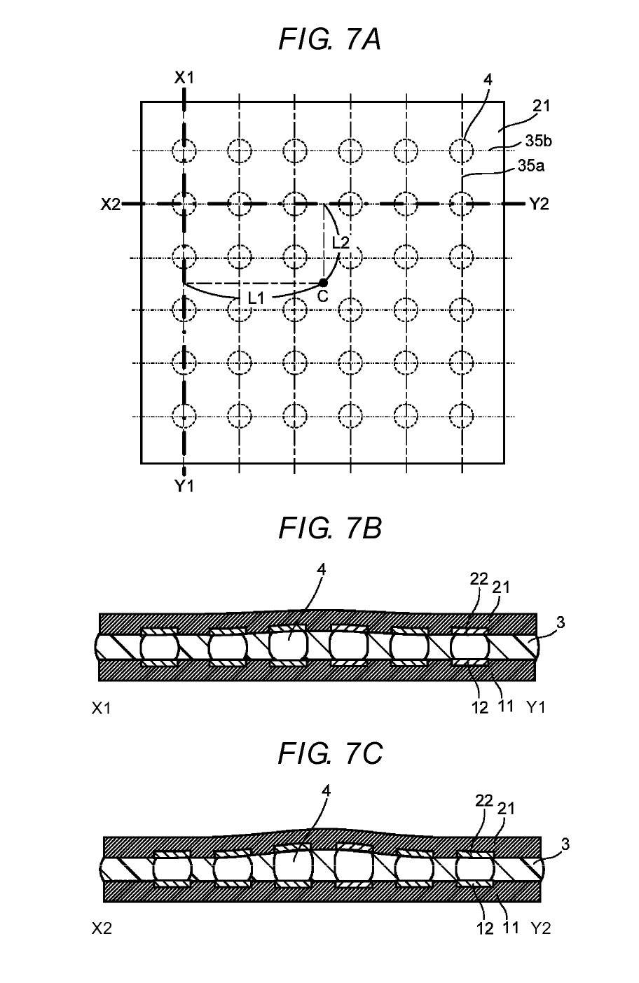

In the semiconductor device described in FIGS. 7A to 7C, when straight lines 35a perpendicularly intersecting one side of the substrate 21 and straight lines 35b parallel to the one side of the substrate 21 are depicted along the plane of the substrate 21, the insulating adhesive layer 3 has a flow distribution that varies with the distance of a perpendicular from the straight line to the geometric center C. The greater the distance L1 of a perpendicular between the straight line 35a and the geometric center C of the substrate 21 or the distance L2 of a perpendicular between the straight line 35b and the geometric center C, the smaller the thickness of the insulating adhesive layer 3 in a region located on the straight line 35a or the straight line 35b.

If the insulating adhesive layer 3 has the above-described flow distribution, as described in FIGS. 7A and 7B, it is preferable to provide the plurality of bumps 4 such that bumps 4 having a lesser distance L1 or L2 from the geometric center C may have a height greater than bumps 4 having a greater distance L1 or L2 from the geometric center C.

If the insulating adhesive layer 3 has the above-described flow distribution, as described in FIGS. 7B and 7C, the longer the distance L1 of the perpendicular and the distance L2 of the perpendicular become, the larger the difference between the minimum value and the maximum value of the heights of the bumps 4 located on the straight line 35a and the straight line 35b may become.

For example, in FIG. 7A, a straight line 35a and a straight line 35b may pass through the geometric center C, dividing the substrate 21 into four first rectangles. Four second rectangles may each have, as an interior angle thereof, one of the interior angles of the substrate 21. The height of the bumps 4 located on the perimeter of the second rectangle which does not coincide with the perimeter of the substrate 21 is a function of the length of the diagonal of the second rectangle. In other words, the larger the second rectangle, that is, the longer the diagonal of the second rectangle, the greater the height of the bumps 4 located on the perimeter of the second rectangle which does not coincide with the perimeter of the substrate 21.

As described above, by adjusting the heights of the plurality of bumps 4 in accordance with the flow distribution of the insulating adhesive layer, even when the thickness of the insulating adhesive layer becomes non-uniform due to the flow distribution, the semiconductor device according to this embodiment may suppress poor bonding by bumps in a region in which the insulating adhesive layer is thick.

### Second Embodiment

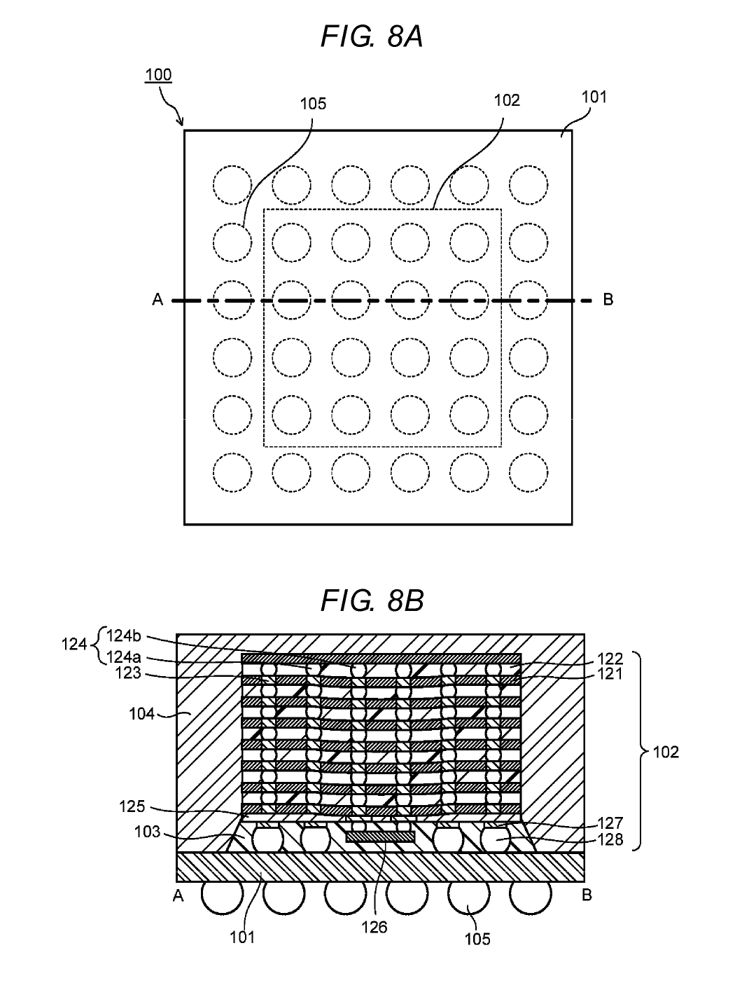

FIGS. 8A and 8B are diagrams showing a structural example of a semiconductor device in which semiconductor chips, are stacked, at least a part of the semiconductor chips having through electrodes such as TSVs. FIG. 8A is a top view and FIG. 8B is a cross-sectional view taken on the line A-B in FIG. 8A. Incidentally, in FIG. 8A, some component elements are not depicted in the drawing for the sake of convenience. For the portions similar to the component elements according to the first embodiment, the descriptions of the first embodiment may be appropriately used.

A semiconductor device 100 includes a wiring substrate 101 having a first surface and a second surface, a chip stack 102 mounted on the first surface of the wiring substrate 101, a sealing resin layer 103 sealing the space between the wiring substrate 101 and the chip stack 102, a sealing resin layer 104 provided to seal the chip stack 102, and external connecting terminals 105 provided on the second surface of the wiring substrate 101.

The wiring substrate 101 may comprise, for example, a resin substrate such as glass epoxy, the resin substrate having a wiring layer on the surface. The first surface of the wiring substrate 101 corresponds to the top surface of the wiring substrate 101 in FIG. 8B, and the second surface corresponds to the under surface of the wiring substrate 101 in FIG. 8B.

The chip stack 102 is electrically connected to the wiring substrate 101 via connecting pads (not pictured) provided in the wiring layer of the wiring substrate 101. The chip stack 102 includes a plurality of semiconductor chips 121 and a semiconductor chip 126. Insulating adhesive layers 122 are provided between the plurality of semiconductor chips 121. Each insulating adhesive layer 122 is formed of an NCF and serves to seal the spaces between the plurality of semiconductor chips. At least some of the semiconductor chips 121 correspond to the substrate 11 or the substrate 21 of FIG. 1. The number of stacked semiconductor chips 121 is not limited to the number of stacked semiconductor chips 121 depicted in FIG. 8B. Moreover, the planar shape of the semiconductor chip 121 is assumed to be a square shape, but the planar shape of the semiconductor chip 121 is not limited thereto.

The insulating adhesive layers 122 correspond to the insulating adhesive layer 3 of FIG. 1. Each insulating adhesive layer 122 has a thickness gradient in which the insulating adhesive layer 122 has a thickness in the geometric center that is greater than the thickness in at least part of the outer edge. As a result, two or more semiconductor chips 121 may curve into a convex shape such that the geometric center regions of the two or more semiconductor chips 121 is closer to the wiring substrate 101 than the side regions of the semiconductor chips 121. The insulating adhesive layer 3 may have any one of the flow distributions described in FIGS. 3A to 3C to FIGS. 7A to 7C, for example. The details of the insulating adhesive layer 3 provided above may also apply to insulating adhesive layers 122.

The plurality of semiconductor chips 121 are electrically connected to one another via a plurality of through electrodes 123 penetrating the semiconductor chips 121 and a plurality of bumps 124 disposed in the insulating adhesive layers 122. For example, by electrically connecting the conductive pads (not pictured) provided in the plurality of semiconductor chips 121 with the through electrodes 123 and the bumps 124, it is possible to connect the plurality of semiconductor chips 121 electrically to one another. As shown in FIG. 8B, through electrodes 123 need not be provided in the semiconductor chip 121 furthest from the wiring substrate 101.

The plurality of bumps 124 include at least a bump 124a having a first height and a bump 124b that is closer to the geometric center of the semiconductor chip 121 than the bump 124a and has a second height which is greater than the first height. The bumps 124 correspond to the bumps 4 in FIG. 1. For example, as is the case with the first example, the heights of the plurality of bumps 124 are adjusted such that bumps 124 have a greater height where the insulating adhesive layer 122 has a greater thickness. The number of the bumps 124 is not limited to the number depicted in FIG. 8B.

The semiconductor chip 121 may comprise, for example, a memory chip or the like. The memory chip may comprise, for example, a storage device such as NAND flash memory. A circuit such as a decoder may be provided in the memory chip.

In the chip stack 102, the semiconductor chip 126 is electrically connected to the semiconductor chips 121 via a rewiring layer 125 provided on the semiconductor chip 121 disposed nearest the semiconductor chip 126. The rewiring layer 125 may serve as a planarizing layer. The chip stack 102 is electrically connected to the wiring substrate 101 via connecting pads 127 and bumps 128 provided on the rewiring layer 125.

The semiconductor chip 126 may comprise, for example, an interface chip or a controller chip. For example, if the semiconductor chip 121 is a memory chip, it is possible to use a controller chip as the semiconductor chip 126. In that case, the controller chip 126 may control writing and reading to and from the memory chip. It is preferable that the semiconductor chip 126 has a dimension smaller than the semiconductor chip 121.

The chip stack 102 may be formed as follows. First, as in the first example of the method for producing the semiconductor device, a second semiconductor chip 121 in which the bump layers and the insulating adhesive layer 122 are formed is stacked on a first semiconductor chip 121 by using a mounter or the like, and a third semiconductor chip 121 with the rewiring layer formed on the surface thereof is finally bonded to the second semiconductor chip. Heat treatment is performed to melt at least part of each of the bump layers or the insulating adhesive layers 122. Cooling is then performed, which hardens the insulating adhesive layers 122 and, at the same time, forms the bumps 124 penetrating the insulating adhesive layers 122 and electrically connecting the semiconductor chips 121.

As the heat treatment, for example, temporary bonding may be performed at a temperature of less than 200° C. and then final bonding may be performed at a temperature of 200° C. or more. For example, temporary bonding may be repeatedly performed every time the semiconductor chip 121 is stacked and, after all the semiconductor chips 121 are stacked, final bonding may be performed. Temporary bonding and final bonding may be repeatedly performed every time the semiconductor chip 121 is stacked.

The semiconductor chip 126 is then mounted on the rewiring layer 125 and the connecting pads 127 and the bumps 128 are formed. After the semiconductor chip 126 is mounted on the rewiring layer 125 and the connecting pads 127 and the bumps 128 are formed, the above-described final bonding may be performed. The chip stack 102 is thus formed.

The chip stack 102 is mounted on the wiring substrate 101 by using a mounter or the like, such that the rewiring layer 125 faces the wiring substrate 101. Bonding between the wiring substrate 101 and the chip stack 102 is performed by using, for example, the pulse heat method or the like. The method is not limited thereto; the chip stack 102 may be mounted by temporarily bonding the wiring substrate 101 and the chip stack 102 and then final bonding by reflow by using the bumps 128.

The sealing resin layer 103 may comprise, for example, underfill resin or the like may be used. The sealing resin layer 103 does not necessarily have to be provided. It is possible to form the sealing resin layer 103 by filling the underfill resin by a dispenser using a needle or the like.

The sealing resin layer 104 may comprise a resin material which contains an inorganic filler such as SiO₂, which is obtained by, for example, mixing an inorganic filler with an insulating organic resin material or the like. The contained inorganic filler occupies 80 to 95 percent by mass of the whole and serves to adjust the viscosity, the hardness, and the like of the sealing resin layer 104. The organic resin material may comprise, for example, epoxy resin.

The external connecting terminals 105 may be formed as follows. Flux is applied to the surface of the wiring substrate 101 not facing the semiconductor chip 126. Solder balls are mounted on the same surface of the wiring substrate 101. The solder balls may be melted in a reflow furnace to be bonded to the connecting pads of the wiring substrate 101. The flux is then removed by a solvent or washing by pure water. The method is not limited thereto; for example, the external connecting terminals 105 may be formed by formation of bumps. The number of the external connecting terminals 105 is not limited to the number described in FIG. 8A.

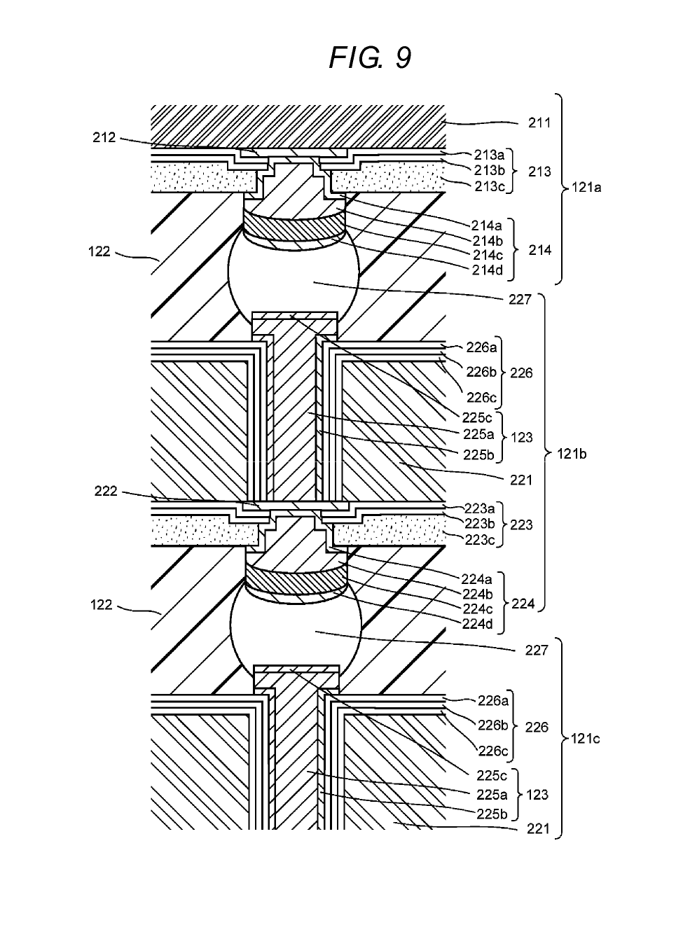

A structural example of the chip stack 102 is described with reference to FIG. 9. FIG. 9 is a cross-sectional view part of a detail of the structural example of the chip stack 102. FIG. 9 depicts a structural example of a junction between a semiconductor chip 121a, a semiconductor chip 121b, and a semiconductor chip 121c as the plurality of semiconductor chips 121 provided in the chip stack 102. The structural example of the chip stack 102 described in FIG. 9 may be appropriately used in the structural example of the semiconductor device 1 depicted in FIG. 1.

The semiconductor chip 121a is the semiconductor chip disposed furthest from the wiring substrate 101. The semiconductor chip 121a includes a semiconductor substrate 211 having a first surface and a second surface (second surface not pictured), electrode pads 212 provided on the first surface of the semiconductor substrate 211, an insulating layer 213 that is provided on the first surface of the semiconductor substrate 211 and has openings over the electrode pads 212, and bump layers 214 making contact with the electrode pads 212 in the openings of the insulating layer 213.

The semiconductor chip 121b is a semiconductor chip in FIG. 8B. The semiconductor chip 121b includes a semiconductor substrate 221 having a first surface and a second surface, electrode pads 222 provided on the first face of the semiconductor substrate 221, an insulating layer 223 that is provided on the first face of the semiconductor substrate 221 and has openings over the electrode pads 222, bump layers 224 making contact with the electrode pads 222 in the openings of the insulating layer 223, through electrodes 123 penetrating the semiconductor substrate 221, an insulating layer 226 provided on the second surface of the semiconductor substrate 221 and between the semiconductor substrate 221 and the through electrodes 123, and bump layers 227 provided on the through electrodes 123.

The semiconductor chip 121c is a semiconductor chip in FIG. 8B. The structure of semiconductor chip 121b may be the same as the structure of semiconductor chip 121c, as well as the structure of any and all other semiconductor chips disposed between semiconductor chip 121a and the semiconductor chip 121 nearest the wiring substrate 101 (the semiconductor chip 121 having the rewiring layer).

The semiconductor substrate 211 and the semiconductor substrate 221 may comprise, for example, a silicon substrate. In the semiconductor substrate 211 and the semiconductor substrate 221, a semiconductor device such as a memory element is formed. A through electrode is not formed in the semiconductor substrate 211. Semiconductor substrate 211 and the semiconductor substrate 221 may also be understood with reference to the discussions of substrate 11 and substrate 21 above.

The electrode pad 212 and the electrode pad 222 may comprise, for example, a single layer or stacked layers of aluminum, copper, titanium, titanium nitride, chromium, nickel, gold, palladium, and the like.

The insulating layer 213 may have stacked layers of a silicon oxide layer 213a, a silicon nitride layer 213b, and an organic resin layer 213c such as polyimide. The insulating layer 223 may have stacked layers of a silicon oxide layer 223a, a silicon nitride layer 223b, and an organic resin layer 223c such as polyimide. The insulating layer 213 and the insulating layer 223 are not limited to the above examples, and the insulating layer 213 or the insulating layer 223 may be formed by using other insulating materials.

The bump layers 214 and the bump layers 224 serve as barrier metal. Each bump layer 214 may comprise stacked layers of a conductive layer 214a formed of copper, a conductive layer 214b having copper as the main ingredient, a conductive layer 214c having nickel as the main ingredient, and a conductive layer 214d having copper as the main ingredient. Each bump layer 224 may have stacked layers of a conductive layer 224a formed of copper, a conductive layer 224b having copper as the main ingredient, a conductive layer 224c having nickel as the main ingredient, and a conductive layer 224d having copper as the main ingredient. The use of copper and nickel in the bump layers 214 and the bump layers 224 may suppress the diffusion of tin or the like contained in the bump layers 227. Moreover, by using copper, it is possible to reduce the production cost.

The bump layers 214 and the bump layers 224 are not limited to the above examples, and the bump layers 214 or the bump layers 224 may be formed by using stacked layers of a conductive layer having copper as the main ingredient and a conductive layer having nickel as the main ingredient; stacked layers of a conductive layer having nickel as the main ingredient and a conductive layer having gold as the main ingredient; stacked layers of a conductive layer having copper as the main ingredient, a conductive layer having nickel as the main ingredient, and a conductive layer having gold as the main ingredient; and the like. The bump layers 214 and the bump layers 224 may form at least part of the bumps 124.

The through electrodes 123 may each have a conductive layer 225a penetrating the semiconductor substrate 221, a conductive layer 225b provided between the conductive layer 225a and the insulating layer 226, and a conductive layer 225c provided on the conductive layer 225a. The conductive layer 225a may comprise, for example, any one or an alloy of nickel, copper, silver, gold, and the like. The conductive layer 225b may comprise, for example, copper, nickel or the like. The conductive layer 225c may comprise, for example, copper, gold or the like. The use of copper as the conductive layer 225b and the conductive layer 225c may reduce the electric resistance of the through electrodes 123. Moreover, it is possible to suppress the diffusion of tin or the like contained in the bump layers 227. The conductive layer 225c does not necessarily have to be provided.

The insulating layer 226 may comprise stacked layers of a silicon oxide layer 226a, a silicon nitride layer 226b, and a silicon oxide layer 226c. The coefficient of linear expansion of the insulating layer 226 using the above materials is lower than the coefficient of linear expansion of the materials (such as copper) forming the through electrodes. Thus, since it is possible to decrease the stress which is placed on the semiconductor chip by providing the insulating layer 226, it is possible to suppress the deformation and cracking of the semiconductor chip. The insulating layer 226 is particularly desirable for the semiconductor device according to this embodiment in which the semiconductor chip 121 is curved by the insulating adhesive layers 122 and the bumps 124. In FIG. 9, the insulating layer 226 is provided along each through electrode 123, but the insulating layer 226 may be provided only on the second surface of the semiconductor substrate 221. At least part of the insulating layer 226 may be provided on the second surface of the semiconductor substrate 221 with each through electrode 123 interposed between a part of the insulating layer 226 and the second surface. The through electrodes 123 and the bump layers 227 may be bonded in the openings.

The bump layers 227 bond the through electrodes 123 and the bump layers 214 or the bump layers 224. The bump layers 227 format least part of the bumps 124. It is preferable that each bump layer 227 makes contact with part of the side surface of each bump layer 224 and part of the side surface of each through electrode 123. As a result, it is possible to increase the bonding strength. The bump layers 227 may comprise, for example, solder such as SnCu, SnAgCu, or the like. The bump layers 227 may alternatively comprise solder balls.

In the semiconductor device according to this embodiment, by changing the height (thickness) of at least one of the bump layers 214, the bump layers 224, and the bump layers 227, for example, in accordance with the flow distribution of the insulating adhesive layers 122, it is possible to change the heights of the bumps 124. By changing the heights of the bumps 124, it is possible to suppress poor bonding caused by the bumps 124 in a region in which the insulating adhesive layer 122 may be thick.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first substrate having a surface;
a plurality of first conductive pads provided on the surface of the first substrate;
a second substrate having a surface;
a plurality of second conductive pads provided below the surface of the second substrate, wherein the surface of the first substrate faces the surface of the second substrate;
a sealing layer sealing a space between the first substrate and the second substrate; and
a plurality of bumps electrically connecting the plurality of first conductive pads and the plurality of second conductive pads,
wherein the plurality of bumps include at least a first bump and a second bump, wherein the second bump is provided in a position closer to a geometric center of the second substrate than the first bump,
the first bump has a first height, and
the second bump has a second height greater than the first height.

2. The semiconductor device according to claim 1, wherein
the plurality of bumps is disposed on a plurality of circumferences of a plurality of circles that share a geometric center of the second substrate,
the first bump is disposed on a circumference of a first circle, the second bump is disposed on a circumference of a second circle, and a diameter of the first circle is greater than a diameter of the second circle, and
a plurality of bumps is disposed on the circumference of the first circle, each of the first circle bumps has a first height, and where a plurality of bumps is disposed on the circumference of the second circle, each of the second circle bumps has a second height.

3. The semiconductor device according to claim 1, wherein
the plurality of bumps are disposed on a plurality of perimeters of a plurality of squares that have sides parallel to at least one side of the second substrate and that share the geometric center of the second substrate, and
the first bump is disposed on a perimeter of a first square, the second bump is disposed on a perimeter of a second square, and the perimeter of the first square is greater than the perimeter of the second square.

4. The semiconductor device according to claim 3, wherein
a plurality of first bumps is disposed on the perimeter of the first square, each of the first bumps having a first height, and a plurality of second bumps is disposed on the perimeter of the second square, each of the second bumps having a second height.

5. The semiconductor device according to claim 1, wherein
the plurality of bumps are disposed on a plurality of perimeters of a plurality of squares that have diagonal lines perpendicular to at least one side of the second substrate and share the geometric center of the second substrate, and
the first bump is disposed on a perimeter of a first square, the second bump is disposed on a perimeter of a second square, and the perimeter of the first square is greater than the perimeter of the second square.

6. The semiconductor device according to claim 5, wherein
a plurality of first bumps is disposed on the perimeter of the first square, each of the first bumps having a first height, and a plurality of second bumps is disposed on the perimeter of the second square, each of the second bumps having a second height.

7. The semiconductor device according to claim 1, wherein
the plurality of bumps is disposed on a plurality of straight lines perpendicular to one side of the second substrate,
the first bump is on a first line, the second bump is on a second line, and a distance from the geometric center of the second substrate to the first line is greater than a distance from the geometric center of the second substrate to the second line, and
a plurality of bumps is disposed on the first line, each of the first line bumps having a first height, and a plurality of bumps is disposed on the second line, each of the second line bumps having a second height.

8. The semiconductor device according to claim 1, wherein
the plurality of bumps is disposed on a plurality of straight lines,
a first straight line is perpendicular to one side of the second substrate and a second straight line is perpendicular to the first line, and
the first bump is on the first line, the second bump is on the second line, and a distance from the geometric center of the second substrate to the first line is greater than a distance from the geometric center of the second substrate to the second line.

9. The semiconductor device according to claim 1, wherein
each of the plurality of bumps comprises a solder layer containing at least tin and a metal bump layer on the solder layer, the metal bump layer comprising at least one metal selected from a group consisting of copper, nickel, and gold.

10. The semiconductor device according to claim 1, wherein
a thickness of the sealing layer is between about 5 μm and about 60 μm, and
a difference between a maximum value and a minimum value of heights of the plurality of bumps is between about 5 μm and about 20 μm.

11. A semiconductor device comprising:
a first substrate having conductive pads above a surface thereof;
a second substrate having conductive pads below a surface thereof; a plurality of bumps electrically connecting the plurality of first conductive pads and the plurality of second conductive pads; and
a sealing layer sealing a space between the first substrate and the second substrate,
wherein the plurality of bumps include at least a first bump and a second bump, wherein the second bump is closer to a geometric center of the first and second substrates and has a height that is greater than a height of the first bump.

12. The semiconductor device according to claim 11, wherein
the plurality of bumps is disposed on a plurality of circumferences of a plurality of circles that share a geometric center of the second substrate,
the first bump is disposed on a circumference of a first circle, the second bump is disposed on a circumference of a second circle, and a diameter of the first circle is greater than a diameter of the second circle, and
a plurality of bumps is disposed on the circumference of the first circle, each of the first circle bumps has a first height, and where a plurality of bumps is disposed on the circumference of the second circle, each of the second circle bumps has a second height.

13. The semiconductor device according to claim 11, wherein
the plurality of bumps are disposed on a plurality of perimeters of a plurality of squares that have sides parallel to at least one side of the second substrate and that share the geometric center of the second substrate, and
the first bump is disposed on a perimeter of a first square, the second bump is disposed on a perimeter of a second square, and the perimeter of the first square is greater than the perimeter of the second square.

14. The semiconductor device according to claim 13, wherein
a plurality of first bumps is disposed on the perimeter of the first square, each of the first bumps having a first height, and a plurality of second bumps is disposed on the perimeter of the second square, each of the second bumps having a second height.

15. The semiconductor device according to claim 11, wherein
the plurality of bumps are disposed on a plurality of perimeters of a plurality of squares that have diagonal lines perpendicular to at least one side of the second substrate and share the geometric center of the second substrate, and
the first bump is disposed on a perimeter of a first square, the second bump is disposed on a perimeter of a second square, and the perimeter of the first square is greater than the perimeter of the second square.

16. The semiconductor device according to claim 15, wherein
a plurality of first bumps is disposed on the perimeter of the first square, each of the first bumps having a first height, and a plurality of second bumps is disposed on the perimeter of the second square, each of the second bumps having a second height.

17. The semiconductor device according to claim 11, wherein
the plurality of bumps is disposed on a plurality of straight lines perpendicular to one side of the second substrate,
the first bump is on a first line, the second bump is on a second line, and a distance from the geometric center of the second substrate to the first line is greater than a distance from the geometric center of the second substrate to the second line, and
a plurality of bumps is disposed on the first line, each of the first line bumps having a first height, and a plurality of bumps is disposed on the second line, each of the second line bumps having a second height.

18. The semiconductor device according to claim 11, wherein
the plurality of bumps is disposed on a plurality of straight lines,
a first straight line is perpendicular to one side of the second substrate and a second straight line is perpendicular to the first line, and
the first bump is on the first line, the second bump is on the second line, and a distance from the geometric center of the second substrate to the first line is greater than a distance from the geometric center of the second substrate to the second line.

19. The semiconductor device according to claim 11, wherein
each of the plurality of bumps comprises a solder layer containing at least tin and a metal bump layer on the solder layer, the metal bump layer comprising at least one metal selected from a group consisting of copper, nickel, and gold.

20. The semiconductor device according to claim 11, wherein
a thickness of the sealing layer is between about 5 μm and about 60 μm, and
a difference between a maximum value and a minimum value of heights of the plurality of bumps is between about 5 μm and about 20 μm.
